(19) United States
(12) Patent Application Publication
(10) Pub. No.: US 2006/0278721 A1
(43) Pub. Date: Dec. 14, 2006

(54) Multimedia memory card

(75) Inventor: Chin Chun Liu, Miaoli Hsien (TW)

Correspondence Address: BACON & THOMAS, PLLC, 625 SLATERS LANE, FOURTH FLOOR, ALEXANDRIA, VA, 22314, US

(73) Assignee: Sun-Light Electronic Technologies Inc., Miaoli Hsien (TW)

(21) Appl. No.: 11/251,823

(22) Filed: Oct. 18, 2005

(30) Foreign Application Priority Data
Jun. 14, 2005 (TW) 94209920

(51) Int. Cl. G06K 19/06; H05K 1/14

(52) U.S. Cl. 235/492; 361/737

(57) ABSTRACT

A multimedia memory card comprises a case cover, a body and a circuit board. A first inserting portion perpendicularly extends from one edge of the case cover. A second inserting portion extends from one end of the first inserting portion. The body has a holding space therein and a supporting baffle formed on inner sides thereof. The circuit board is provided with an electronic component on one surface thereof. The electronic component is received in the holding space of the body. The circuit board is joined onto the supporting baffle on inner sides of the body. The case cover is joined onto one side of the body, and the first inserting portion and the second inserting portion are inserted inside the body, thereby making the case cover and the body tightly joined together.

### BACKGROUND OF THE INVENTION

1. Field of the Invention

The present invention relates to a multimedia memory card, and more particularly, to an improved multimedia memory card which has the strongest bonding strength between a case cover and a body.

2. The Description of the Related Prior Art

With great advances in integrated circuit technology and materials, there are wider integrated circuits applications. Moreover, various integrated circuit products are produced, with more powerful and tend to thin and compact, examples are electronic dictionaries, digital cameras, digital video cameras, and so on. Taking the digital camera as an example, as a large volume of digital information is required to be recorded, an electronic media, such as memory, is needed for the digital camera, thereby developing a multimedia memory card (MMC) by integrating a memory chip and a thin card. Hence, the card so formed is capable of storing information and is very compact and fits for the tendency of electronic products, so it becomes widely applicable.

With development in digital technology, a wide range of digital electronic products comes into existence; relies on improving the same old audiovisual products to achieve maximum storage functionality with the minimum memory required, such as digital video cameras, digital cameras, multimedia players, digital projectors, digital audio recorders, etc. As the majority of the above-mentioned information and electronic products are portable, information is required to be stored in a compact MMC.

However, for the conventional MMC, it is to first insert a circuit board into a frame, then the upper and the lower case body, having the same structure, are joined onto the frame, and afterwards the upper and the lower case body are buckled to the frame by buckling the buckling elements; however, when the MMC made by this method is subjected to external forces or bending forces, insufficient resistance to twist of MMC may cause structural loosening, detachment, sinking, deformation, and breaking. And undoubtedly, there is room for improvement of MMC volume, in order to achieve compactness and thinness required for modern digital image storage equipment.

In a known assembling structure of an electric card, the electric card is securely joined onto the interior of the connection parts around a conducting case by means of partial plastic materials of the plastic frame. The connection parts are in the shape of holes, saws, or inverted hooks. However, the joint of the plastic frame and the conducting case has not strong bonding strength.

### SUMMARY OF THE INVENTION

It is the primary object of the present invention to provide a multimedia memory card with one end of a first inserting portion of the multimedia memory card extends a second inserting portion. By inserting the second inserting portion into a body, the bonding strength of the case cover and the body of multimedia memory card has been enhanced.

To achieve the aforementioned objects of the present invention, the MMC card comprises a case cover, a body and a circuit board. A first inserting portion perpendicularly extends from one edge of the case cover. A second inserting portion extends from one end of the first inserting portion. The body has a holding space and a supporting baffle formed on inner sides of the body. An electronic component is disposed on one surface of the circuit board. The electronic component is contained in the holding space of the body. The circuit board is joined on the supporting baffle on the inner sides of the body. The case cover is joined onto one side of the body. The first inserting portion and the second inserting portion are inserted inside the body, thereby making the case cover and the body tightly joined.

According to one preferred embodiment of the present invention, the case cover is made of metallic material.

According to one preferred embodiment of the present invention, the body is made of plastic material.

According to one preferred embodiment of the present invention, the second inserting portion is O-shaped.

According to one preferred embodiment of the present invention, the second inserting portion is L-shaped.

According to one preferred embodiment of the present invention, the second inserting portion is U-shaped.

According to one preferred embodiment of the present invention, the circuit board is glued onto the supporting baffle on the inner sides of the body by a thermal tape though heating and pressing.

### BRIEF DESCIPTION OF THE DRAWINGS

The structure and the technical means adopted by the present invention to achieve the above and other objects can be best understood by referring to the following detailed description of the preferred embodiments and the accompanying drawings, wherein

FIG. 1 shows a perspective view of the multimedia memory card according to the present invention.

FIG. 2 shows an exploded view of the multimedia memory card according to the present invention.

FIG. 3A shows a perspective view of the case cover according to the present invention.

FIG. 3B shows an enlarged view of part A in FIG. 3A.

FIG. 3C shows an enlarged view of part B in FIG. 3A.

FIG. 3D shows an enlarged view of part C in FIG. 3A.

FIG. 4A shows a cross-sectional view along line A-A of FIG. 1 of the present invention.

FIG. 4B shows an enlarged view of part D in FIG. 4A.

FIG. 5A shows a cross-sectional view along line B-B of FIG. 1 of the present invention.

FIG. 5B shows an enlarged drawing of part E in FIG. 5A.

FIG. 6A shows a cross-sectional view along line C-C of FIG. 1 of the present invention.

FIG. 6B shows an enlarged view of part F in FIG. 6A.

FIG. 6C shows an enlarged view of part G in FIG. 6A.

FIG. 7A shows a cross-sectional view along line D-D of FIG. 1 of the present invention.

FIG. 7B shows an enlarged view of part H in FIG. 7A.

FIG. 7C shows an enlarged view of part I in FIG. 7A.

FIG. 8 shows a cross-sectional view of the O-shaped second inserting portion according to the present invention.

FIG. 9 shows a cross-sectional view of the L-shaped second inserting portion according to the present invention.

FIG. 10 shows a cross-sectional view of the U-shaped second inserting portion according to the present invention.

### DETAILED DESCRIPTION OF THE PREFERRED EMBODIMENTS

While the invention has been described by way of examples and in terms of preferred embodiments, it is to be understood that those who are familiar with the subject art can carry out various modifications and similar arrangements and procedures described in the present invention and also achieve the effectiveness of the present invention. Hence, it is to be understood that the description of the present invention should be accorded with the broadest interpretation to those who are familiar with the subject art, and the invention is not limited thereto.

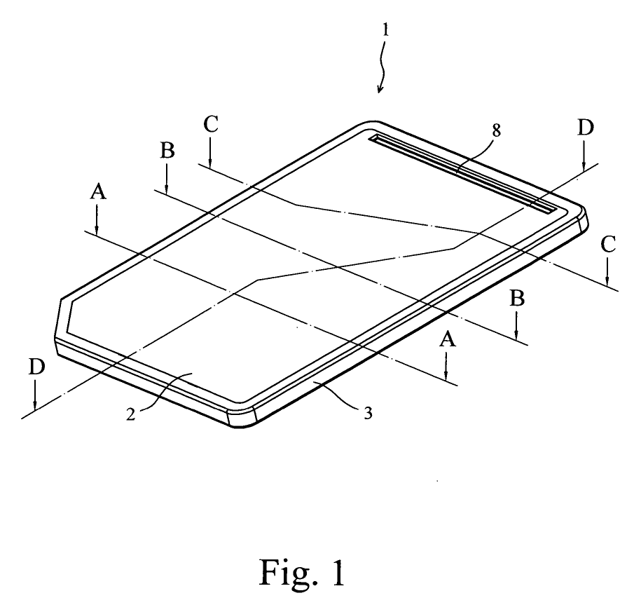

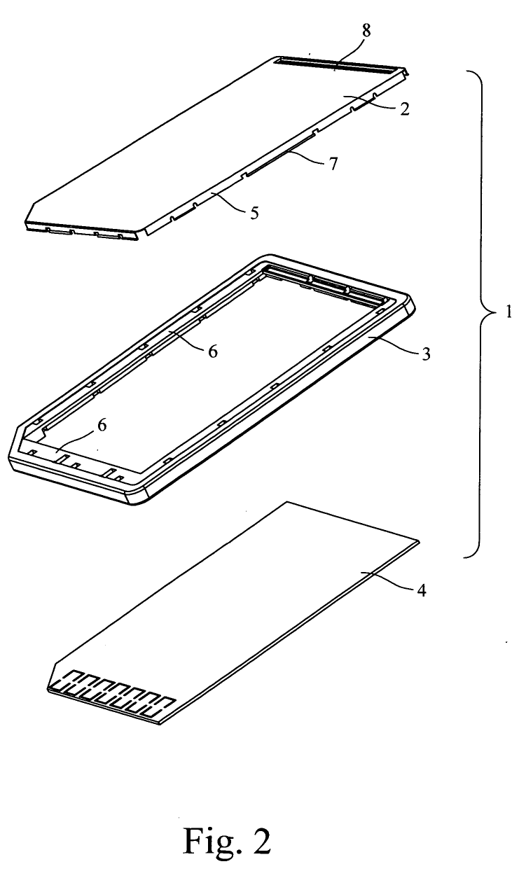

Referring to FIG. 1 and FIG. 2, the drawings respectively show one perspective view and one exploded view of the multimedia memory card of the present invention. The multimedia memory card 1 of the present invention comprises a case cover 2, a body 3 and a circuit board 4. A first inserting portion 5 perpendicularly extends from one edge of the case cover 2. A second inserting portion 7 extends from one end of the first inserting portion 5. The body 3 has a holding space and a supporting baffle 6 formed on inner sides of the body 3. The circuit board 4 is provided with an electronic component (not shown in the drawing) on one surface thereof. The case cover 2, the body 3 and the circuit board 4 are assembled in a sandwich type, thereby forming the multimedia memory card 1 of the present invention.

The case cover 2 is made of metallic material, and one side of the outer surface of the case cover 2 is provided with a groove 8, which enables the user to draw out the multimedia memory card 1 of the present invention. The body 3 is made of plastic material, and the electronic component is contained in the holding space of the body 3. The circuit board 4 is joined onto the supporting baffle 6 on the inner sides of the body 3. The case cover 2 is joined to the body 3 by insert molding such that the electronic component is contained in the holding space of the body 3. The circuit board 4 is glued onto the supporting baffle 6 by a thermal tape through heating and pressing.

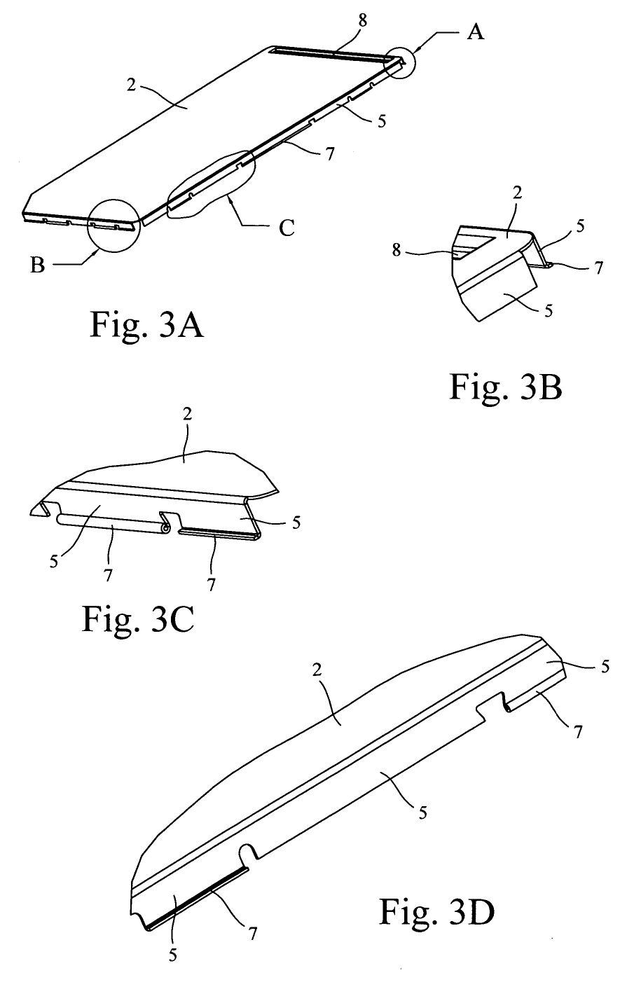

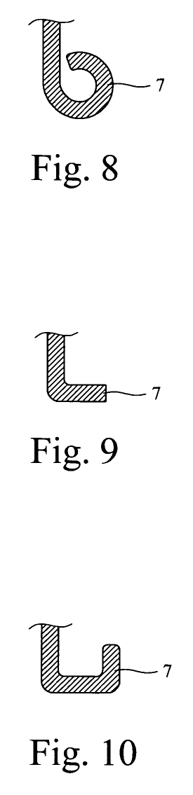

Referring to FIG. 3A, FIG. 3B, FIG. 3C and FIG. 3D, the drawings show one perspective view of the case cover 2, one enlarged view of part A in FIG. 3A, one enlarged view of part B in FIG. 3A, and one enlarged view of part C in FIG. 3A respectively. According to a preferred embodiment of the present invention, a plurality of the first inserting portions 5 perpendicularly extends from one edge of the case cover 2 and the intervals between the first inserting portions 5 are different. A second inserting portion 7 extends from one end of each of some of the first inserting portions 5. The second inserting portion 7 is O-shaped (referring to FIG. 8), or in L-shaped, that is dovetail-shaped (referring to FIG. 9.) The case cover 2 can have a combination of the O-shaped second inserting portions 7 and the L-shaped second inserting portions 7. When the case cover 2 joins to the body 3 by insert molding, the first inserting portion 5 and the second inserting portion 7 are inserted in the body 3, thereby making the case cover 2 tightly joined to the body 3 with strongest bonding strength. As such, the multimedia memory card 1 of the present invention has high impact resistance to prevent detached or damaged.

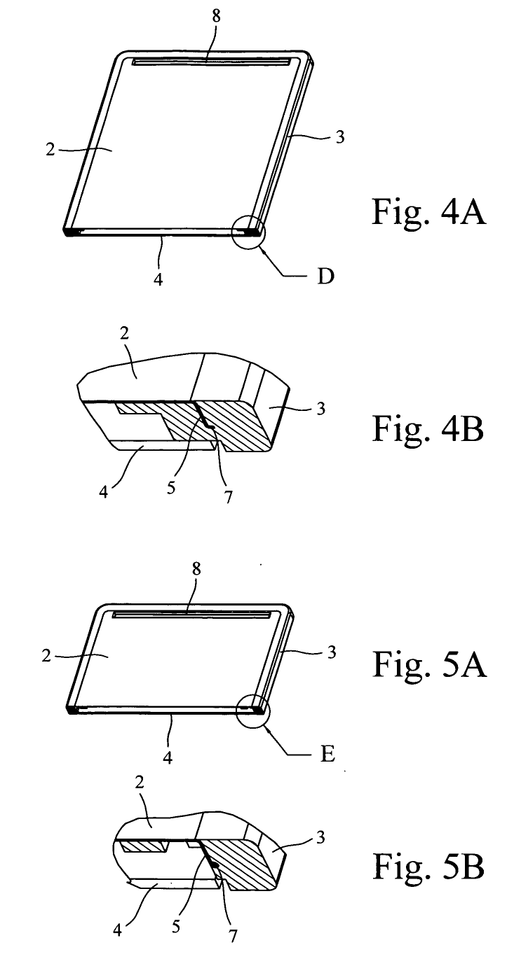

Referring to FIG. 4A and FIG. 4B, the drawings show one cross-sectional view along line A-A of FIG. 1 and one enlarged view of part D in FIG. 4A respectively. The first inserting portion 5 of the case cover 2 and the L-shaped second inserting portion 7 (in the shape of a dovetail) are inserted inside the body 3, thereby making the case cover 2 tightly joined to the body 3.

Referring to FIG. 5A and FIG. 5B, the drawings show one cross-sectional view along line B-B of FIG. 1 and one enlarged view of part E in FIG. 5A respectively. The first inserting portion 5 of the case cover 2 and the O-shaped second inserting portion 7 are inserted inside the body 3, thereby making the case cover 2 tightly joined to the body 3.

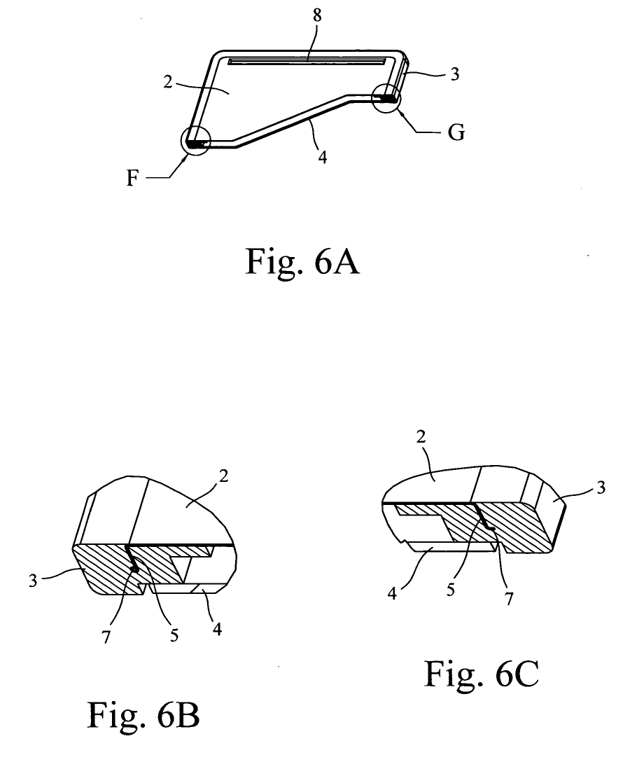

Referring to FIG. 6A, FIG. 6B and FIG. 6C, the drawings show one cross-sectional view along line C-C of FIG. 1, one enlarged view of part F in FIG. 6A, and one enlarged view of part G in FIG. 6A respectively. The first inserting portion 5 of the case cover 2, the O-shaped second inserting portion 7, and the L-shaped second inserting portion 7 (in the shape of a dovetail) are inserted inside the body 3, thereby making the case cover 2 tightly joined to the body 3.

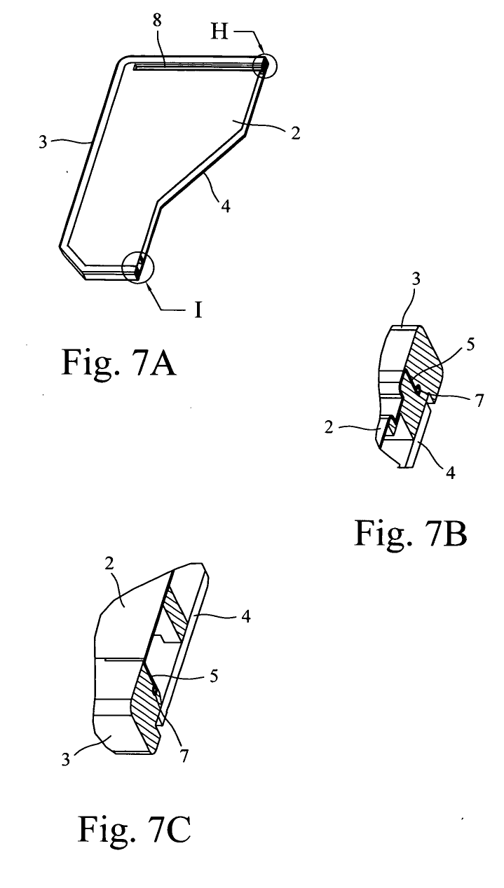

Referring to FIG. 7A, FIG. 7B and FIG. 7C, the drawings show one cross-sectional view along line D-D of FIG. 1, an enlarged view of part H in FIG. 7A; an enlarged view of part I in FIG. 7A respectively. The first inserting portion 5 of the case cover 2 and the O-shaped second inserting portion 7 are inserted inside the body 3, thereby making the case cover 2 tightly joined to the body 3.

FIG. 8, FIG. 9 and FIG. 10 respectively show a cross-sectional view of the O-shaped second inserting portion, the L-shaped second inserting portion, and the U-shaped second inserting portion. According to a preferred embodiment of the multimedia memory card 1 of the present invention, those second inserting portions 7 are in the shape of O, L, and U.

While the invention has been described by way of examples and in terms of preferred embodiments, it is to be understood that the invention is not limited thereto. To the contrary, those who are familiar with the subject art can carry out various modifications and similar arrangements and procedures, under the scope of appended claims and broadest interpretation. For example, the second inserting portion can be in the shape of U (referring to FIG. 10); according to the embodiment disclosed by combining the second inserting portion and the body, the second inserting portion can be in the shape of either one of the followings: O, L, U, and the combination (referring to FIG. 10.)

What is claimed is:

1. A multimedia memory card comprising:
a case cover with one edge thereof perpendicularly extending a first inserting portion, and one end of said first inserting portion extending a second inserting portion;
a body having a holding space therein and a supporting baffle formed on inner sides of said body; and
a circuit board provided with an electronic component on one surface thereof, said electronic component received in the holding space of said body and said circuit board joined onto said supporting baffle on the inner sides of said body;
wherein said case cover is joined onto one side of said body, said first inserting portion and said second inserting portion are inserted inside said body, thereby making said case cover and said body tightly joined together.

2. The multimedia memory card as claimed in claim 1, wherein said case cover is made of metallic material.

3. The multimedia memory card as claimed in claim 1, wherein said body is made of plastic material.

4. The multimedia memory card as claimed in claim 1, wherein said second inserting portion is O-shaped.

5. The multimedia memory card as claimed in claim 1, wherein said second inserting portion is U-shaped.

6. The multimedia memory card as claimed in claim 1, wherein said second inserting portion is L-shaped.

7. The multimedia memory card as claimed in claim 1, wherein said circuit board is glued onto said supporting baffle on the inner sides of said body by a thermal tape through heating and pressing.
